(19) United States
(12) Patent Application Publication
(10) Pub. No.: US 2013/0168147 A1
(43) Pub. Date: Jul. 4, 2013

(54) ELECTRONIC DEVICE

(71) Applicants: Yasuhiro Kohara, Osaka-shi (JP); Hijiri Nakahara, Osaka-shi (JP)

(72) Inventors: Yasuhiro Kohara, Osaka-shi (JP); Hijiri Nakahara, Osaka-shi (JP)

(21) Appl. No.: 13/822,303

(22) PCT Filed: Sep. 29, 2011
(86) PCT No.: PCT/JP2011/072383

§ 371 Date: Mar. 12, 2013

(30) Foreign Application Priority Data
Oct. 8, 2010 (JP) 2010-228804

(51) Int. Cl. H05K 1/02

(52) U.S. Cl. CPC H05K 1/0254
USPC 174/260

(57) ABSTRACT

Provided is an electronic device having a novel structure that makes it possible to simplify a structure needed for countermeasure against static electricity, while avoiding adverse effect to the function of the electronic device. An electronic device includes: a substrate (12) on which circuit elements (16) are provided; internal lines (32a to 32g) that are formed on the substrate and are connected electrically with the circuit elements (16); terminal portions (38a to 38g) that are provided on a side opposite to connection ends of the internal lines (32a to 32g) connected with the circuit elements (16) and are connected electrically with an external circuit; and external lines (42a to 42g) that are connected to the terminal portions (38a to 38g) and extend from the terminal portions (38a to 38g) toward an edge of the substrate (12), wherein the external lines (42a to 42g) include: high resistance portions (44a to 44g) provided at connection ends thereof connected with the terminal portions (38a to 38g); and low resistance portions (43a to 43g) having smaller electric resistances than the high resistance portions (44a to 44g).

### TECHNICAL FIELD

The present invention relates to an electronic device.

### BACKGROUND ART

In an electronic device such as a touch panel, a terminal portion electrically connected with an outer circuit is formed in a periphery of a substrate on which circuit elements are provided. In such an electronic device, there is a risk of occurrence of electrostatic breakdown during the manufacture or the like. The electrostatic breakdown is damage to the circuit element caused by static electricity that is generated around an electronic device and flows from the terminal portion to the circuit element.

Then, an electrooptic device has been proposed in which a lead line that is routed from a terminal to a peripheral circuit includes a low resistance portion and a high resistance portion having a higher resistance than that of the low resistance portion, as disclosed in JP 2009-75506A (Patent Document 1).

However, in the electrooptic device disclosed in Patent Document 1, the high resistance portion and the terminal are formed in different layers, with an interlayer insulating film being interposed therebetween. Besides, the high resistance portion is routed within the region where the terminal is formed. Therefore, there is a problem of complexity in a structure needed for countermeasure against static electricity.

In addition, a lead line is provided between the terminal and the peripheral circuit in the electrooptic device disclosed in Patent Document 1. Therefore, an electric signal transferred between an outer circuit connected electrically with the terminal and the peripheral circuit also flows through the routing line. As a result, there is a risk that an inconvenience such as a delay in transmission of the electric signal could occur, which would adversely affect the function of the electrooptic device.

### DISCLOSURE OF INVENTION

It is an object of the present invention to provide an electronic device having a novel structure that makes it possible to simplify a structure needed for countermeasure against static electricity, while avoiding adverse effect to the function of the electronic device.

An electronic device of the present invention includes: a substrate on which a circuit element is provided; an internal line that is formed on the substrate and is connected electrically with the circuit element; a terminal portion that is provided on a side opposite to a connection end of the internal line connected with the circuit element and is connected electrically with an external circuit; and an external line that is connected to the terminal portion and extends from the terminal portion toward an edge of the substrate, wherein the external line includes: a high resistance portion provided at a connection end thereof connected with the terminal portion; and a low resistance portion having a smaller electric resistance than the high resistance portion.

With the electronic device of the present invention, it is possible to simplify a structure needed for countermeasure against static electricity, while avoiding adverse effect to the function of the electronic device.

### BRIEF DESCRIPTION OF DRAWINGS

FIG. 1 is a plan view showing a touch panel as an electronic device according to Embodiment 1 of the present invention.

FIG. 2 is cross-sectional view taken along a line II-II in FIG. 1.

FIG. 3 is a cross-sectional view taken along a line III-III in FIG. 1.

FIG. 4 is an enlarged plan view showing principal members of the touch panel shown in FIG. 1.

FIG. 5 is an enlarged cross-sectional view showing principal members taken along, and viewed in a direction indicated by, an arrow line V-V in FIG. 4.

FIG. 6 is a plan view showing a touch panel as an electronic device according to Embodiment 2 of the present invention.

FIG. 7 is an enlarged plan view showing principal members of the touch panel shown in FIG. 6.

FIG. 8 is an enlarged cross-sectional view showing principal members taken along a line VIII-VIII in FIG. 7.

FIG. 9 is a plan view showing a touch panel as an electronic device according to Embodiment 3 of the present invention.

FIG. 10 is an enlarged plan view showing principal members of the touch panel shown in FIG. 9

### DESCRIPTION OF THE INVENTION

An electronic device according to one embodiment of the present invention includes: a substrate on which a circuit element is provided; an internal line that is formed on the substrate and is connected electrically with the circuit element; a terminal portion that is provided on a side opposite to a connection end of the internal line connected with the circuit element and is connected electrically with an external circuit; and an external line that is connected to the terminal portion and extends from the terminal portion toward an edge of the substrate, wherein the external line includes: a high resistance portion provided at a connection end thereof connected with the terminal portion; and a low resistance portion having a smaller electric resistance than the high resistance portion (the first configuration).

In the first configuration, during the manufacture of the electronic device, or the like, static electricity generated around the electronic device invades through the low resistance portion of the external line positioned on the substrate edge side with respect to the terminal portion. The static electricity thus invading through the low resistance portion of the external line is prevented from further invading toward the terminal portion side by the high resistance portion provided at the connection end of the external line connected with the terminal portion. Therefore, in the first configuration, the countermeasure against static electricity can be achieved with a simple structure.

Further, the external line through which static electricity invades is positioned on the substrate edge side with respect to the terminal portion. This prevents electric signals for realizing functions of the electronic device, such as electric signals from an outer circuit, from flowing through the high resistance portion of the external line. As a result, this makes it possible to avoid adverse effect to the functions of the electronic device.

The second configuration is the first configuration further including an insulating film that covers at least a part of the terminal portion and has an opening that opens above the terminal portion, wherein the external line formed on the insulating film is in contact with the terminal portion via the opening, and a portion of the external line positioned in the opening is the high resistance portion. In such a configuration, the high resistance portion can be formed easily. Further, the electric resistance of the high resistance portion can be changed by changing the size of the opening.

The third configuration is the second configuration further modified so that the opening is smaller than a portion of the external line that falls on the terminal portion as viewed in a plan view of the substrate. In such a configuration, the electric resistance of the high resistance portion can be increased easily.

The fourth configuration is the second or third configuration further modified so that the opening is smaller than a cross-section of the external line in a direction perpendicular to a direction in which the external line extends. In such a configuration, the electric resistance of the high resistance portion can be increased easily.

The fifth configuration is the first configuration further modified so that the external line and the terminal portion are formed on the same layer. In such a configuration, the external line and the terminal portion can be formed at the same time.

The sixth configuration is the fifth configuration further modified so that a cross-section of the external line in a direction perpendicular to a direction in which the external line extends is minimized at the high resistance portion. In such a configuration, the electric resistance of the high resistance portion can be increased easily.

The seventh configuration is the fifth or sixth configuration further modified so that the external line is provided integrally with the terminal portion. In such a configuration, the contact between the terminal portion and the high resistance portion can be achieved easily.

The eighth configuration is the fifth or sixth configuration further modified so that the external line is formed as a member separate from the terminal portion, and a part of the high resistance portion is formed so as to overlap the terminal portion. In such a configuration, the contact between the terminal portion and the high resistance portion can be achieved easily.

Hereinafter, more specific embodiments of the present invention are explained with reference to the drawings. The drawings referred to hereinafter show, in a simplified manner, only principal members illustration of which is needed for explanation of the present invention, among constituent members of embodiments of the present invention, for convenience of explanation. Therefore, an electronic device according to the present invention may include arbitrary members that are not shown in the drawings that the present specification refers to. Further, the dimensions of the members shown in the drawings do not faithfully reflect actual dimensions of constituent members, dimensional ratios of the constituent members, etc.

### Embodiment 1

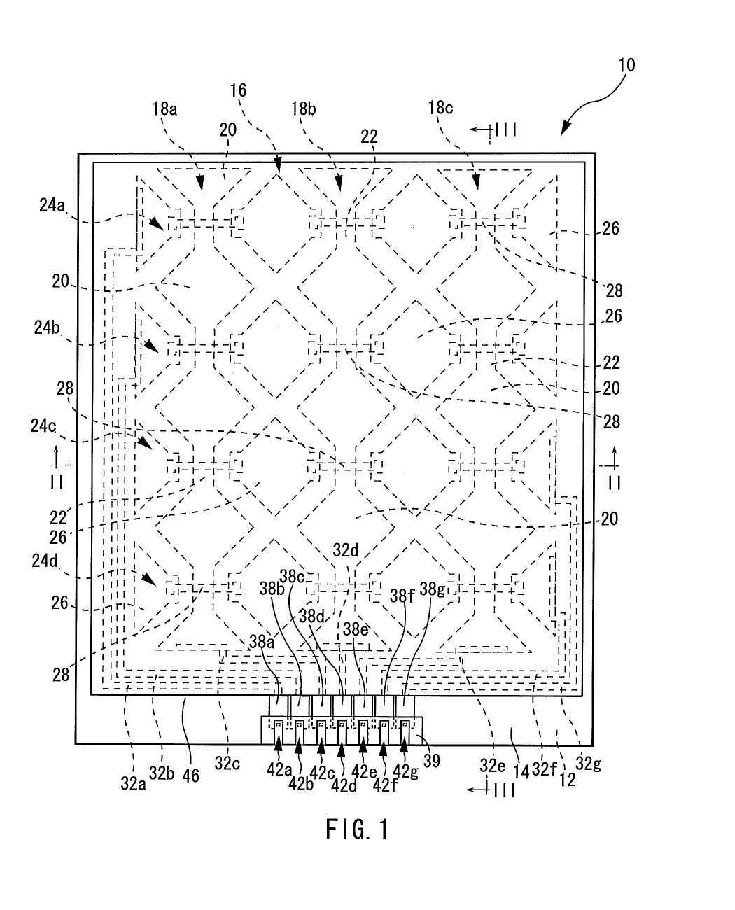

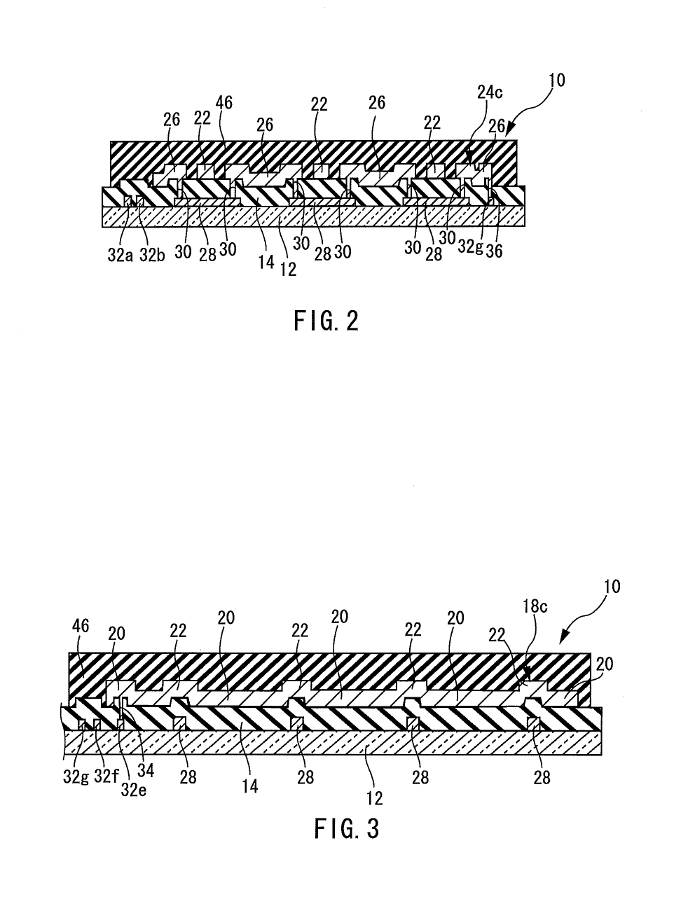

FIGS. 1 to 5 show a touch panel 10 as an electronic device according to Embodiment 1 of the present invention.

The touch panel 10 includes a substrate 12. As the substrate 12, a glass substrate or the like, for example, can be used.

On the substrate 12, an insulating film 14 is formed. As the insulating film 14, an inorganic film such as a silicon oxide film or a silicon nitride film, for example, can be used.

On an upper surface of the substrate 12, touch electrodes 16 as circuit elements are formed. The region where the touch electrodes 16 are formed is the input region of the touch panel 10.

The touch electrodes 16 include a plurality of vertical electrodes 18a to 18c and a plurality of horizontal electrodes 24a to 24d. It should be noted that in the drawing, appropriate numbers of the vertical electrodes 18a to 18c and the horizontal electrodes 24a to 24c are shown, so that the configuration can be understood easily, but arbitrary numbers of these electrodes may be provided instead.

As the vertical electrodes 18a to 18c, indium tin oxide (ITO) films or the like, for example, can be used. The vertical electrodes 18a to 18c include a plurality of island-form electrode portions 20 and a plurality of bridge lines 22. It should be noted that in the drawing, appropriate numbers of island-form electrode portions 20 and the bridge line portions 22 are shown, so that the configuration can be understood easily, but arbitrary numbers of these island-form electrode portions and bridge line portions may be provided instead.

These island-form electrode portions 20 and bridge lines 22 are formed so as to be alternate on the insulating film 14, and in this manner the vertical electrodes 18a to 18c extend along one edge of the substrate 12 (one edge extending in the vertical direction of FIG. 1).

The horizontal electrodes 24a to 24d include a plurality of island-form electrode portions 26 and a plurality of bridge lines 28. It should be noted that in the drawing, appropriate numbers of island-form electrode portions 26 and the bridge line portions 28 are shown, so that the configuration can be understood easily, but arbitrary numbers of these island-form electrode portions and bridge line portions may be provided instead.

The island-form electrode portions 26 are formed on the insulating film 14. As the island-form electrode portions 26, indium tin oxide (ITO) films or the like, for example, can be used.

The bridge line portions 28 are formed on the substrate 12 and covered with the insulating film 14. As each bridge line portion 28, for example, a laminate metal film obtained by laminating a titanium film, an aluminum film, and a titanium nitride film in this order, or the like, can be used.

These island-form electrode portions 26 and bridge line portions 28 are formed so as to be alternate as viewed in the plan view of the substrate 12, so that the horizontal electrodes 24a to 24d extend along one edge of the substrate 12 (one edge extending in the horizontal direction of FIG. 1). It should be noted that the electric connection between the island-form electrode portions 26 and the bridge line portions 28 is provided via contact holes 30 formed so as to pass through the insulating film 14 in the thickness direction.

On the substrate 12, a plurality of internal lines 32a to 32g are formed. It should be noted that an appropriate number of the internal lines 32a to 32g are shown in the drawing, so that the configuration can be understood easily, but an arbitrary number of the lines may be provided instead.

As each of the internal lines 32a to 32b, for example, a metal film obtained by laminating a titanium film, an aluminum film, and a titanium nitride film in this order, or the like, can be used.

Among the internal lines 32a to 32g, the internal lines 32c to 32e are connected to the vertical electrodes 18a to 18c, respectively. The other internal lines 32a, 32b, 32f, and 32g are connected to the horizontal electrodes 28a to 28d, respectively. In other words, one internal line is connected to each of the plurality of the vertical electrodes and the horizontal electrodes. It should be noted that the electric connection between the internal lines 32c to 32e and the vertical electrodes 18a to 18c, respectively, and the electric connection between the internal lines 32a, 32b, 32f, and 32g and the horizontal electrodes 24a to 24d are provided via contact holes 34 and 36 formed so as to pass through the insulating film 14 in the thickness direction.

At extension ends of the internal lines 32a to 32g, terminal portions 38a to 38g are formed, respectively. As each of the terminal portions 38a to 38g, for example, a metal film formed by laminating a titanium film, an aluminum film, and a titanium nitride film in this order, or the like, can be used. Each of the terminal portions 38a to 38g is formed in a width greater than the width of the internal lines 32a to 32g so as to extend in a direction in which the internal lines 32a to 32g extend, and has a rectangular shape as viewed in the plan view of the substrate 12.

Ends of the terminal portions 38a to 38g on the side to the edge of the substrate 12 are covered with an insulating film 39. In other words, the terminal portions 38a are partially uncovered with the insulating film 39.

The insulating film 39 covers ends of all of the terminal portions 38a to 38g on the side to the edge of the substrate 12. The insulating film 39 is formed so as to extend to the edge of the substrate 12.

The insulating film 39 is formed through the same step as the insulating film 14 in the manufacturing process. This makes it possible to simplify the method for manufacturing the touch panel 10.

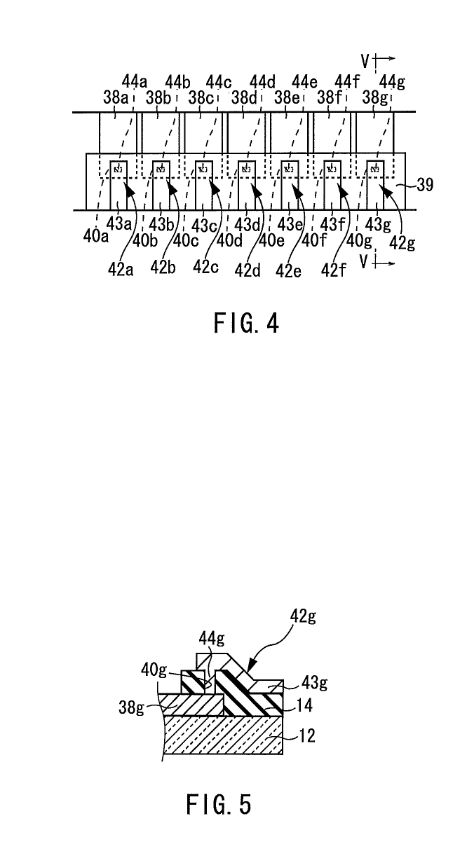

As shown in the enlarged view of FIG. 4, openings 40a to 40g are formed in the insulating film 39 so as to open above the terminal portions 38a to 38g, respectively. The openings 40a to 40g pass through the insulating film 39 in the thickness direction, each in an approximately uniform rectangular cross-sectional shape.

As shown in FIGS. 4 and 5, external lines 42a to 42g are formed on the insulating film 39 so as to be brought into contact with the terminal portions 38a to 38g via the openings 40a to 40g, respectively. As the external lines 42a to 42g, for example, metal films such as aluminum films, indium tin oxide (ITO) films, or the like can be used.

The external lines 42a to 42g, the vertical electrodes 18, and the island-form portions 26 of the horizontal electrodes 24a to 24d are formed through the same step of the manufacturing process. This makes it possible to simplify the method for manufacturing the touch panel 10.

The external lines 42a to 42g include extension portions 43a to 43g, respectively. The extension portions 43a to 43g are formed so as to extend in an approximately constant width each.

The extension portions 43a to 43g extend from positions that fall on the openings 40a to 40g toward an edge of the substrate 12, as viewed in the plan view of the substrate 12. In the present embodiment, the extension ends of the extension portions 43a to 43g are positioned at the edge of the substrate 12. It should be noted that short rings (not shown) for transferring static electricity are connected to the extension ends of the extension portions 43a to 43g, before the touch panel 10 is cut out of a mother substrate for touch panels (not shown).

The extension portions 43a to 43g are formed so as to extend, each in a width smaller than the dimension of each of the terminal portions 38a to 38g in the widthwise direction (the dimension in the horizontal direction in FIG. 4). Parts of the extension portions 43a to 43g that fall on the terminal portions 38a to 38g as viewed in the plan view of the substrate 12 are formed to be larger than the openings 40a to 40g. Each cross-section of the extension portions 43a to 43g in the direction (the horizontal direction in FIG. 4) perpendicular to the extension direction thereof (the vertical direction in FIG. 4) has an area smaller than each opening area of the openings 40a to 40g.

The external lines 42a to 42g include contact portions 44a to 44g, respectively, as shown in FIGS. 4 and 5. The contact portions 44a to 44g enter the openings 40a to 40g and are in contact with the terminal portions 38a to 38g. Thus, the external lines 42a to 42g are electrically connected with the terminal portions 38a to 38g.

Further, each opening area of the openings 40a to 40g is set smaller than each area of cross-sections of the extension portions 43a to 43g in direction perpendicular to the extension direction of the extension portions 43a to 43g (each area of cross-sections of the extension portions 43a to 43g). Therefore, electric resistances of the contact portions 44a to 44g increase most at the external lines 42a to 42g.

In other words, in the present embodiment, high resistance portions are realized by the contact portions 44a to 44g, while low resistance portions are realized by the extension portions 43a to 43g.

Particularly, in the present embodiment, each opening area of the openings 40a to 40g is set smaller than each area of the openings of the contact holes 30. This causes each electric resistance of the contact portions 44a to 44g provided in the openings 40a to 40g to be greater than that of the connection portions between the island-form electrode portions 28 and the bridge line portions 30 provided in the contact holes 30.

Each electric resistance of the contact portions 44a to 44g is desirably greater than each electric resistance of circuit elements (the touch electrodes 16 in the present embodiment) of the touch panel 10. This makes it easier to prevent electrostatic breakdown of the circuit elements of the touch panel 10.

A protective film 46 is formed on the top face side of the substrate 12. As the protective film 46, for example, an acrylic resin film, a silicon oxide film, or the like can be used. The protective film 46 covers the vertical electrodes 22a to 22c and the island-form electrode portions 26 of the horizontal electrodes 28a to 28d.

Such a touch panel 10 is used, for example, in a state of being attached to a display panel such as a liquid crystal panel. In the state where the touch panel 10 is attached to the display panel, the input region of the touch panel 10 and the display region of the display panel coincide with each other.

A flexible printed board (not shown) as an external circuit is connected to the touch panel 10. More specifically, connection terminals provided in the flexible printed board are connected to the terminal portions 38a to 38g via an anisotropic conductive film (ACF) (not shown). This allows the flexible printed board and the terminal portions 38a to 38g to be connected electrically via the anisotropic conductive film (not shown).

The touch panel 10 has such a configuration that a touched position is detected by detecting a change in capacitances of electrostatic capacitors that are formed between a finger of an observer and some of the vertical electrodes 22a to 22c positioned close to the finger and some of the horizontal electrodes 28a to 28d positioned close to the finger when the finger touches a cover glass substrate (not shown) arranged so as to cover the protective film 46. In other words, the touch panel 10 of the present embodiment is a so-called projected capacitive touch panel.

In such a touch panel 10, static electricity generated around the touch panel 10 invades the touch panel 10 via the extension portions 43a to 43g of the external lines 42a to 42g, in the process of manufacturing the touch panel 10. The static electricity invading from the extension portions 43a to 43g of the external lines 42a to 42g is prevented from going to the side of the terminal portions 38a to 38g beyond the contact portions 44a to 44g, by the contact portions 44a to 44g as the static electricity entry prevention means. Therefore, with a simple structure, the countermeasure against static electricity can be provided.

Besides, the external lines 42a to 42g, through which static electricity invades, are positioned on the side to the edge of the substrate 12, with respect to the terminal portions 38a to 38g. This makes it possible to prevent electric signals for realizing the functions of the touch panel 10, such as electric signals supplied from external circuits, from flowing through the contact portions 44a to 44g. As a result, this makes it possible to avoid adverse effect to the functions of the touch panel 10.

The contact portions 44a to 44g that prevent invasion of static electricity are provided in the openings 40a to 40g, respectively. Therefore, by setting opening areas of the openings 40a to 40g appropriately, electric resistances of the contact portions 44a to 44g can be changed.

The openings 40a to 40g are set smaller than portions of the extension portions 43a to 43g that fall on the terminal portions 38a to 38a as viewed in the plan view of the substrate 12. This makes it possible to make the openings 40a to 40g smaller. As a result, this makes it easier to make the contact portions 44a to 44g positioned in the openings 40a to 40g, respectively, to have greater electric resistances.

Each opening area of the openings 40a to 40g is set smaller than each area of cross-sections of the extension portions 43a to 43g (each area of the cross-sections of the extension portions 43a to 43g in the direction perpendicular to the extension direction of the extension portions 43a to 43g). This makes it easier to increase electric resistances of the contact portions 44a to 44g present in the openings 40a to 40g.

### Embodiment 2

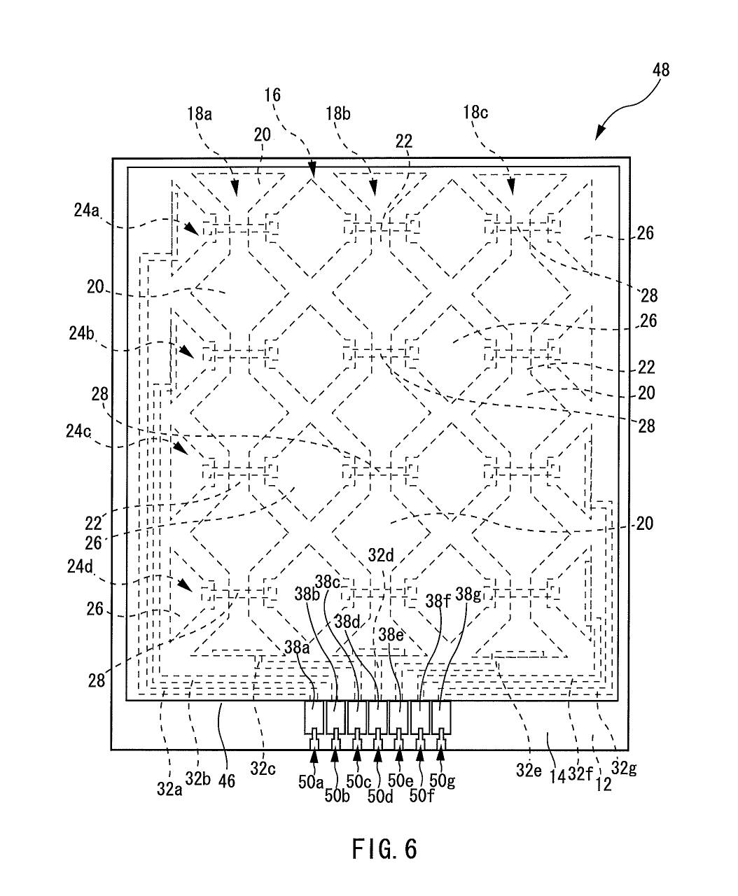

Next, a touch panel 48 as an electronic device according to Embodiment 2 of the present invention is explained based on FIGS. 6 to 8. It should be noted that members and portions in Embodiment 2 described below and Embodiment 3 to be described later having the same structures as those in Embodiment 1 are denoted by the same reference numerals as those in Embodiment 1 in the drawings, and detailed descriptions of the same are omitted.

The touch panel 48 of the present embodiment is different from the touch panel 10 of Embodiment 1 in that external lines 50a to 50g are provided in place of the external lines 43a to 43g. Besides, the insulating film 39 is not provided. As a result, the state of contact between the external lines 50a to 50g and the terminal portions 38a to 38g is different from the state of contact between the external lines 42a to 42g and the terminal portions 38a to 38b in Embodiment 1.

The external lines 50a to 50g are formed directly on the substrate 12, not via the insulating film 39. It should be noted that short rings (not shown) for transferring static electricity are connected to the extension ends of the external lines 50a to 50g, before the touch panel 48 is cut out of a mother substrate for touch panels that is not shown.

As the external lines 50a to 50g, metal films such as aluminum films, indium tin oxide (ITO) films, or the like, for example, can be used.

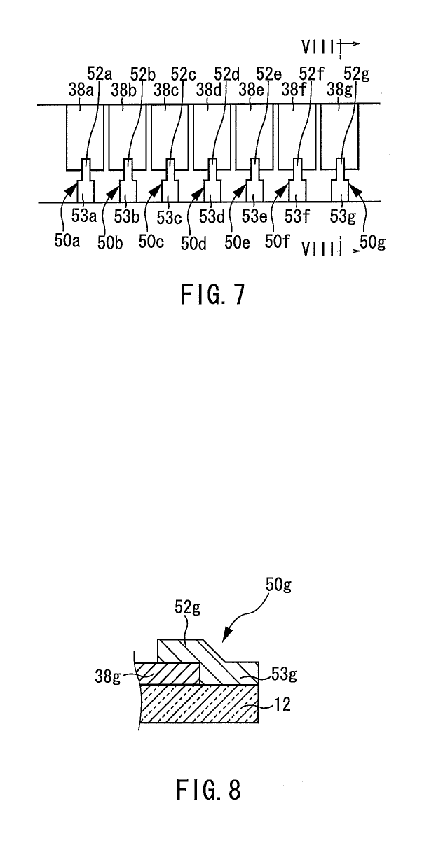

Contact portions 52a to 52g are formed with respect to the external lines 50a to 50g, respectively, at the ends thereof on the side opposite to the edge of the substrate 12. Each width of the contact portions 52a to 52g (the dimension in the horizontal direction in FIG. 7) is set smaller than each width of portions 53a to 53g that are the other portions of the external lines 50a to 50g than the contact portions 52a to 52g, respectively. The other portions 53a to 53g of the external lines 50a to 50g than the contact portions 52a to 52g are formed so as to extend in an approximately constant width. Therefore, the external lines 50a to 50g have the minimum widths at the contact portions 52a to 52g. Besides, each thickness (the thickness dimension) of the external lines 50a to 50g is approximately constant over the entire lengths in the extension direction. Therefore, the external lines 50a to 50g have the maximum electric resistances at the contact portions 52a to 52g as static electricity invasion prevention means, respectively. In the present embodiment, high resistance portions are realized by the contact portions 52a to 52g, and low resistance portions are realized by the other portions 53a to 53g of the external lines 50a to 50g than the contact portions 52a to 52g.

The contact portions 52a to 52g partially overlap the terminal portions 38a to 38g. This allows the contact portions 52a to 52g to be in contact with top faces and side faces of the terminal portions 38a to 38g. As a result, the external lines 50a to 50g are electrically connected with the terminal portions 38a to 38g, respectively.

It should be noted that as is clear from the foregoing explanation, the external lines 50a to 50g are formed after the terminal portions 38a to 38g are formed.

### Embodiment 3

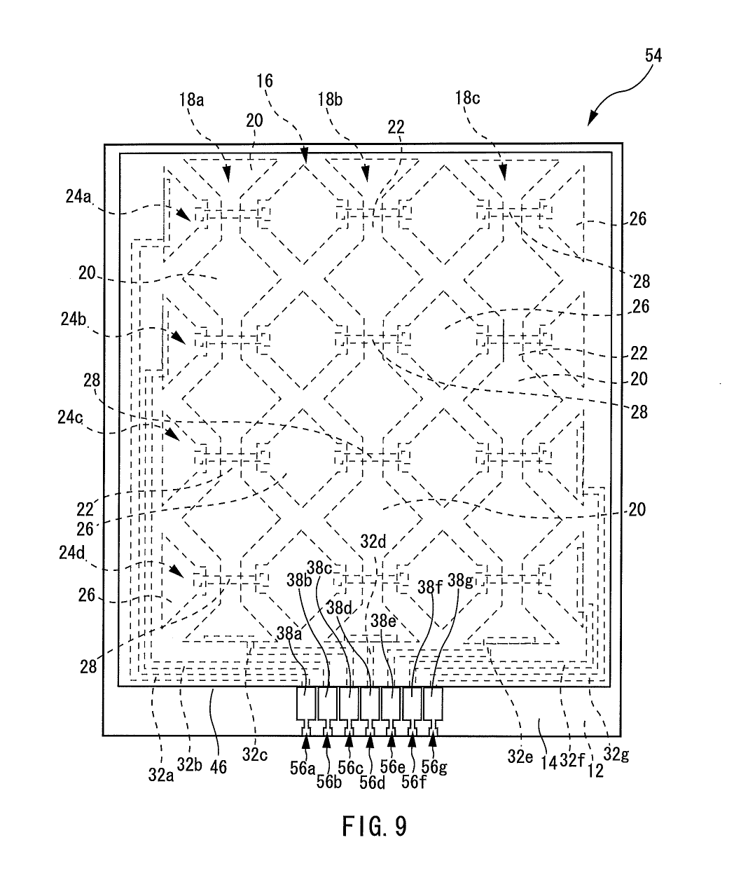

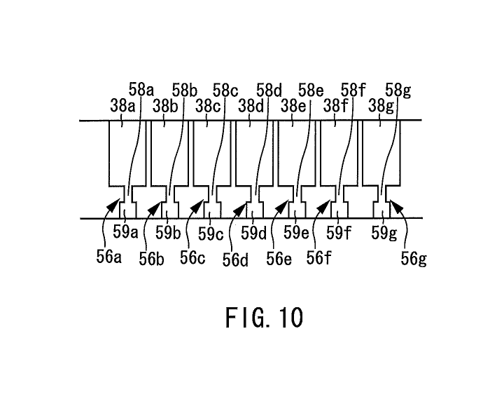

Next, a touch panel 54 as an electronic device according to Embodiment 3 of the present invention is explained based on FIGS. 9 and 10. The touch panel 54 of the present embodiment is different from the touch panel 10 of Embodiment 1 in that external lines 56a to 56g are provided in place of the external lines 43a to 43g. Besides, the insulating film 39 is not provided. As a result, the state of contact between the external lines 56a to 56g and the terminal portions 38a to 38g is different from the state of contact between the external lines 42a to 42g and the terminal portions 38a to 38b in Embodiment 1.

The external lines 56a to 56g are formed integrally with the terminal portions 38a to 38g, respectively. In other words, the external lines 56a to 56g are formed through the same step as the internal lines 32a to 32g, the bridge lines 28 of the horizontal electrodes 24 at 24d, and the terminal portions 38a to 38g.

The external lines 56a to 56g include contact portions 58a to 58g, respectively. Each width of the contact portions 58a to 58g (the dimension in the horizontal direction in FIG. 10) is set smaller than each width of portions 59a to 59g that are the other portions of the external lines 56a to 56g than the contact portions 58a to 58g, respectively. The other portions 59a to 59g of the external lines 56a to 56g than the contact portions 58a to 58g are formed so as to extend in an approximately constant width. Therefore, the external lines 56a to 56g have the minimum widths at the constant portions 58a to 58g. Besides, each thickness (the thickness dimension) of the external lines 56a to 56g is approximately constant over the entire lengths in the extension direction. Therefore, the external lines 56a to 56g have the maximum electric resistances at the contact portions 58a to 58g as static electricity invasion prevention means, respectively. In other words, in the present embodiment, high resistance portions are realized by the contact portions 58a to 58g, and low resistance portions are realized by the other portions 59a to 59g of the external lines 56a to 56g than the contact portions 58a to 58g. The external lines 56a to 56g are in contact with the terminal portions 38a to 38g at the contact portions 58a to 58g.

In the case of such a touch panel 54, the external lines 56a to 56g can be formed when the internal lines 32a to 32g, the bridge lines 28 of the horizontal electrodes 24a to 24d, and the terminal portions 38a to 38g are formed. This makes it possible to simplify the method for manufacturing the touch panel 54.

So far the embodiments of the present invention have been described in detail, but these are merely examples. The present invention is not limited at all by the above-described embodiments.

For example, Embodiments 1 to 3 are explained with reference to specific examples in which the present invention is applied to a projected capacitive touch panel. The touch panel, to which the present invention can be applied, however, is not limited to the projected capacitive touch panel. The present invention can be applied to touch panels of various types, such as a surface capacitive touch panel, a resistive touch panel, an infrared touch panel, an ultrasonic touch panel, an electromagnetic touch panel, and the like. The present invention can be applied also to a liquid crystal panel, a plasma display panel (PDP), an organic ET, (electroluminescence) panel, an inorganic EL panel, or the like.

Further, in Embodiments 1 to 3 described above, the contact portions 44a to 44g, 52a to 52g, and 58a to 58g may be formed as separate portions from the other portions of the external lines 42a to 42g, 50a to 50g, and 56a to 56g. This allows the contact portions 44a to 44g, 52a to 52g, and 58a to 58g to be formed with a different material from the material for the other portions than the contact portions 44a to 44g, 52a to 52g, and 58a to 58g in the external lines 42a to 42g, 50a to 50g, and 56a to 56g, so that electric resistances of the contact portions 44a to 44g, 52a to 52g, and 58a to 58g are different from those of the other portions than the contact portions 44a to 44g, 52a to 52g, and 58a to 58g. Consequently this makes it unnecessary to minimize the cross-sectional areas of the external lines 42a to 42g, 50a to 50g, and 56a to 56g at the contact portions 44a to 44g, 52a to 52g, and 58a to 58g.

1. An electronic device comprising:
a substrate on which a circuit element is provided;
an internal line that is formed on the substrate and is connected electrically with the circuit element;
a terminal portion that is provided on a side opposite to a connection end of the internal line connected with the circuit element and is connected electrically with an external circuit; and
an external line that is connected to the terminal portion and extends from the terminal portion toward an edge of the substrate,
wherein the external line includes:
a high resistance portion provided at a connection end thereof connected with the terminal portion; and
a low resistance portion having a smaller electric resistance than the high resistance portion.

2. The electronic device according to claim 1, further comprising an insulating film that covers at least a part of the terminal portion and has an opening that opens above the terminal portion,
wherein the external line formed on the insulating film is in contact with the terminal portion via the opening, and
a portion of the external line positioned in the opening is the high resistance portion.

3. The electronic device according to claim 2, wherein the opening is smaller than a portion of the external line that falls on the terminal portion as viewed in a plan view of the substrate.

4. The electronic device according to claim 2, wherein the opening is smaller than a cross-section of the external line in a direction perpendicular to a direction in which the external line extends.

5. The electronic device according to claim 1, wherein the external line and the terminal portion are formed on the same layer.

6. The electronic device according to claim 5, wherein a cross-section of the external line in a direction perpendicular to a direction in which the external line extends is minimized at the high resistance portion.

7. The electronic device according to claim 5, wherein the external line is provided integrally with the terminal portion.

8. The electronic device according to claim 5,
wherein the external line is formed as a member separate from the terminal portion, and
a part of the high resistance portion is formed so as to overlap the terminal portion.
